(19) United States
(12) Patent Application Publication
(10) Pub. No.: US 2010/0186672 A1
(43) Pub. Date: Jul. 29, 2010

(54) Plasma processing apparatus

(76) Inventors: Koji Okuda, Shunan (JP); Tsutomu Nakamura, Hikari (JP); Michiaki Kobayashi, Kudamatsu (JP); Masakazu Isozaki, Shunan (JP); Hidenobu Tanimura, Kudamatsu (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 12/379,643

(22) Filed: Feb. 26, 2009

(30) Foreign Application Priority Data
Jan. 26, 2009 (JP) 2009-013769

(51) Int. Cl. C23C 16/00

(52) U.S. Cl. 118/723 R

(57) ABSTRACT

A plasma processing apparatus composed of a processing chamber in a vacuum vessel to which a gas is fed to form a plasma, a sample stage in which a channel for a heat exchange medium is formed, beams for supporting the sample stage in the horizontal direction, a cylindrical space at atmospheric pressure formed below the channel in the sample stage, coupling paths for communicating the inner wall of the cylindrical space with the exterior of the vacuum vessel, a piping conduit for medium formed in the coupling path, a drive mechanism to drive pins for a wafer, and metal blocks covering junctions between the piping conduits for medium and the sample stage, whereby a gas at high temperature is supplied to between the metal blocks and is exhausted through the coupling path.

### BACKGROUND OF THE INVENTION

The present invention relates to plasma processing apparatus for processing a substrate-like sample such as a semiconductor wafer by using a plasma formed in a processing chamber inside a vacuum vessel and more particularly, to a plasma processing apparatus for processing a sample while regulating the temperature of a sample stage which is arranged in the processing chamber and has its top surface mounted with the sample.

A semiconductor production apparatus for processing the sample such as the semiconductor wafer has hitherto been required of high accuracy and high reliability. Conventionally, to satisfy such requirements, it has been practiced that the sample is processed while adjusting the temperature of the sample stage carrying and holding the sample within the processing chamber to a desired value.

For example, the general practice is such that a channel for passage of a heat exchange medium such as water is arranged in a member of high heat conductivity such as metal member constituting the sample stage, and a refrigerant, adjusted in its temperature to a predetermined value by means of a temperature regulator connected to the channel through a piping conduit, is circulated by being fed to the interior of the sample stage and drained out of it. In the conventional technique, the setting of temperature by the temperature regulator is adjusted highly accurately to a value suitable for the processing in order that the temperatures of the sample stage and of the sample such as the semiconductor wafer carried and held thereon can be adjusted to intended values, thus making the sample processing highly accurate.

On the other hand, in order to realize high integration of semiconductor devices in recent years, a variety of kinds of materials have been used for the semiconductor device. The semiconductor production apparatus has been required to properly process a thin film formed on a semiconductor wafer made of many kinds of materials as above and to meet this requirement, the range of temperature regulation by the aforementioned circulation of the heat exchange medium has been broadened. With the aim of processing the sample at a temperature lower than heretofore, it has been considered to circulate a heat exchange medium having its temperature adjusted to more lower values through the interior of the sample stage.

An example of such a technique has been known as disclosed in JP-A-10-64985.

The above related art, however, fails to consider the following points sufficiently, raising problems.

More specifically, the substrate-like sample such as the semiconductor wafer is processed at a temperature lower than that of a room in which the apparatus is installed (generally, the semiconductor production apparatus, for example, a plasma etching processing apparatus is installed in the room such as a clean room where the temperature and humidity is regulated and the number of dust particles is limited, and the temperature of the room is set to so called the room temperature around 25 degree C.) and therefore, the sample stage is cooled by circulating a heat exchange medium at a temperature lower than that in the room. In this phase, the temperature of the ambience nearby the sample stage or nearby the inner periphery of a vacuum vessel containing the sample stage therein falls below the dew point, resulting that the channel for feeding the refrigerant and the sample stage will possibly be dew-condensed. For example, when a refrigerant at a temperature lower than the ambient temperature is circulated, the dew condensation will possibly take place at a piping conduit constituting the refrigerant channel on the feeding side which exposes to the ambience.

There is the possibility that water droplets due to the dew condensation as above will corrode or erode the piping conduit or spatter to cause corrosion or short-circuiting of the neighboring units and devices, resulting in their erroneous operations. Especially, if the portion exposed to the lower temperature is located inside the vacuum vessel of semiconductor production apparatus and the trouble shooting work from the outside is difficult to achieve, there results a problem that the erosion and the erroneous operation will occur highly frequently to impair the reliability. The aforementioned related art does not consider such a problem.

An object of the present invention is to provide a plasma processing apparatus capable of suppressing the dew condensation at the sample stage located in the processing chamber inside the vacuum vessel to improve the reliability.

### SUMMARY OF THE INVENTION

According to this invention, the above object can be accomplished by a plasma processing apparatus comprising:

a substantially cylindrically shaped processing chamber arranged in a vacuum vessel and having its decompressed interior to which a gas for processing is fed and in which a plasma is formed;

a substantially cylindrically shaped sample stage arranged inside the processing chamber with intervention of a space between the sample stage and the inner sidewall surface of the processing chamber surrounding the sample stage and adapted to carry a sample such as a wafer to be processed on its top surface;

an opening formed at the bottom of the processing chamber below the sample stage and adapted for exhausting the processing gas;

a channel for medium which is formed helically or concentrically in the sample stage and through which a heat exchange medium for adjusting the temperature of the sample stage flows;

beams arranged horizontally between the sample stage and the inner sidewall of said processing chamber to support the sample stage in the processing chamber;

a cylindrical space defined in the interior of the sample stage below the channel and having its interior in communication with the atmospheric pressure;

a coupling path formed inside each of the beams and adapted to communicate the inner wall of the cylindrical space with the atmospheric-pressure space external of the vacuum vessel;

a plurality of piping conduits for medium which are so formed in the coupling paths as to connect to the channel and through which the heat exchange medium flows;

a drive mechanism arranged in the interior of the cylindrical space centrally thereof and adapted to drive a plurality of pins for up/down movement of a wafer above the top surface of the sample stage;

a plurality of metal blocks arranged around the outer periphery of the drive mechanism to cover a plurality of junctions of the plurality of piping conduits for medium to the sample stage; and

a gas supply path which passes through the interior of the coupling path and has an opening between the plural blocks inside the cylindrical space and the drive mechanism, and through which a gas heated to a given temperature is circulated, whereby ambient gas prevailing in the cylindrical space is exhausted to the exterior of the vacuum vessel by way of the coupling path.

Further, the refrigerant piping conduit has its junction connected to the ceiling surface of the cylindrical space through an opening formed in the inner sidewall of the cylindrical space, and the block has a flat surface parallel to the ceiling surface or the bottom surface of the cylindrical space and a side surface set up at right angles to the flat surface.

Further, the sample stage is arranged concentrically with the processing chamber and supported by a plurality of the beams and at least one of the plurality of piping conduits for medium and the gas supply path are arranged in the coupling path formed in one of the plural beams.

Further, the sample stage is arranged concentrically with the processing chamber and supported by three or more of the beams and one of the plurality of piping conduits for medium and the gas supply path are arranged in one of the coupling paths formed in one of the plural beams.

Further, in the center portion and the outer peripheral side of the sample stage, first and second medium channels are provided, respectively, through which heat exchange media adjusted to different temperatures are circulated, first and second medium piping conduits, connected to the respective first and second medium channels and arranged in the interior of individual coupling paths in the respective beams, are provided, and first and second metal blocks arranged to cover the junctions of the first and second medium piping conduits, respectively, are provided, whereby the gas from the gas supply path is supplied to inbetween defined by the first and second metal blocks.

Further, a plurality of beams are arranged around the sample stage arranged concentrically with the processing chamber so as to be symmetrical to the vertical center axis of the sample stage.

Further, the drive mechanism includes a plurality of pins arranged around the center of the sample stage in the interior thereof, a plurality of arms each connected to the bottom of each of the plurality of pins and extending from the center of the sample stage to the outer periphery thereof and an actuator connected to the arms and being vertically telescopic between the ceiling surface of the cylindrical space and the arm, and besides a telescopic bellows is provided which is arranged around each of the plurality of pins and connected to the ceiling surface of the cylindrical space, having its interior hermetically sealed from its exterior.

In the plasma processing apparatus as above, by supplying a gas heated or dehumidified to have a low content of water to the space at the atmospheric pressure, dew condensation can be prevented from taking place in the space at the atmospheric pressure.

Other objects, features and advantages of the invention will become apparent from the following description of the embodiments of the invention taken in conjunction with the accompanying drawings.

### BRIEF DESCRIPTION OF THE DRAWINGS

FIG. 1 is a top view schematically showing the construction of a vacuum processing apparatus having a plasma processing apparatus according to an embodiment of the invention.

FIG. 2 is a longitudinal sectional view schematically showing the construction of a principal part of a vacuum process unit in the FIG. 1 embodiment, with an upper vessel is enlarged.

FIG. 3 is a longitudinal sectional view schematically showing in an enlarged manner the construction of the ample stage and its periphery in the FIG. 2 example.

FIG. 4 is a cross-sectional view schematically showing the construction of the vacuum vessel and sample stage in the FIG. 3 example.

### DETAILED DESCRIPTION OF THE EMBODIMENTS

Embodiments of the present invention will now be described with reference to the accompanying drawings.

### Embodiment

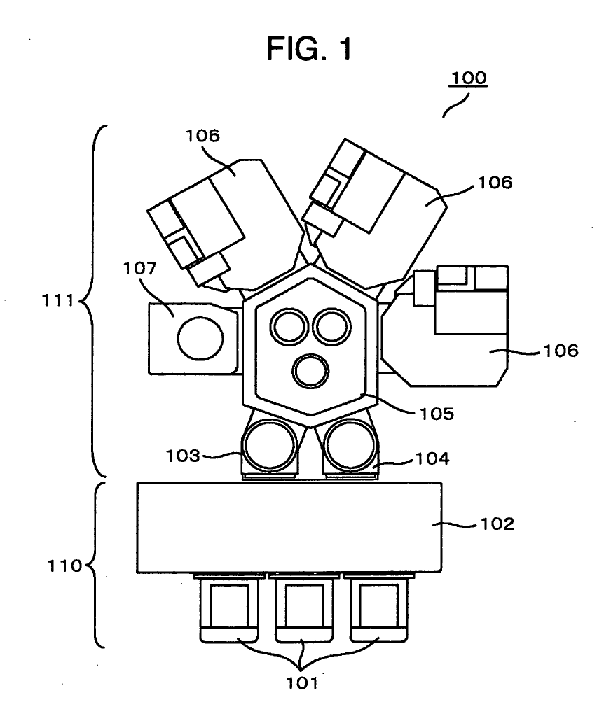

An embodiment of the present invention will be described hereunder in greater detail by using FIGS. 1 to 4.

A vacuum processing apparatus having a plasma processing apparatus according to the present embodiment of the invention is schematically illustrated in top view form in FIG. 1. In the figure, the vacuum processing apparatus, generally designated at reference numeral 100, comprises an atmospheric block 110 at the front of the apparatus corresponding to the lower side on the drawing and a vacuum block 111 at the rear side corresponding to the upper side on the drawing, these blocks being connected with each other at the back of the atmospheric block 110.

The atmospheric block 110 is a site where a substrate-like sample such as a semiconductor wafer is handled under the atmospheric pressure and includes a plurality of cassette stands 101 which are so positioned at the front of apparatus as to be juxtaposed in the horizontal direction and on which sample storage cassettes are carried, and an atmospheric sample-transfer chamber 102 of a substantially cuboid shape having its front side connected or attached with the cassette stands 101. The atmospheric sample-transfer chamber 102 has its interior space in which the sample is transferred under the atmospheric pressure by means of an atmospheric sample-transfer robot for transferring the sample.

On the backside of the atmospheric sample-transfer chamber 102 of atmospheric block 110, the vacuum block 111 is arranged. Lock chambers 103 and 104 constituting the vacuum block 111 are connected to the back of the atmospheric sample-transfer chamber 102. The lock chambers 103 and 104 are connected at their rear portions in the vertical direction on the drawing to a vacuum sample-transfer chamber 105.

The vacuum sample-transfer chamber 105 is constructed of a vacuum vessel having a polygonal plane form (hexagon in the present embodiment) and its plural sidewall surfaces corresponding to each side of the hexagon are connected to the lock chambers 103 and 104 and a plurality of vacuum process units 106 and 107 as well. With the lock chambers 103 and 104 connected to the back surface of the atmospheric sample-transfer chamber 102 of atmospheric block 110, the plurality of vacuum process units 106 and 107 of the vacuum block 111 can be in communication, as necessary, with the atmospheric sample-transfer chamber 102 and sample storage cassettes of the atmospheric block 110.

The lock chambers 103 and 104 are connected to a vacuum evacuation unit not shown so that the pressure in the interior of each of the lock chambers may be adjustable between the atmospheric pressure and a pressure of high vacuum degree in the interior of the vacuum sample-transfer chamber 105. Integrally attached to the front and back of the lock chamber are gate valves for opening and closing the interior of the lock chamber so as to open and hermetically close the interior. Further, in a space inside each of the lock chambers 103 and 104 in which the pressure is adjustable, a sample stage not shown having its top surface on which the sample is carried is arranged, and structurally, the pressure can be changed while the sample being carried on the sample stage and held thereby. In the present embodiment, the lock chambers 103 and 104 are configured as being capable of storing the sample therein in any case of loading for storing an unprocessed sample in the vacuum process unit 106 or 107 and unloading for storing a processed sample.

Further, in the interior of the vacuum sample-transfer chamber 105, a gate valve (not shown) is arranged between the internal transfer chamber and the vacuum process unit 106 or 107 so as to open or hermetically close a passage for sample transfer through which communication therebetween can be set up. The gate valve is opened when the sample is transferred and it establishes closure between the interior of the vacuum process unit 106 or 107 and the interior of the transfer chamber to set up hermetic seal between the interior of the vacuum process unit 106 or 107 and the interior of the transfer chamber in the course of processing of the sample.

As described above, in the vacuum processing apparatus 100, samples stored in a sample storage cassette set on the cassette stand 101 connected to the atmospheric sample-transfer chamber 102 are transferred one by one to the interior of the lock chamber 103 or 104 by means of the transfer robot accommodated in the atmospheric sample-transfer chamber 102. After the sample has been stored in a storage chamber inside the lock chamber 103 or 104 at the atmospheric pressure and carried on the sample stage, the gate value on the side of atmospheric sample-transfer chamber 102 is closed and the interior of the lock chamber 103 or 104 is decompressed.

After the pressure in the interior of the lock chamber 103 or 104 has reached a vacuum degree equivalent to that in the vacuum sample-transfer chamber 105, the gate valve on the side of vacuum sample-transfer chamber 105 is opened so that the sample may be taken out by means of the transfer robot accommodated in the vacuum sample-transfer chamber 105 and delivered to any one of the vacuum process units 106 and 107 so as to be processed at its surface. After completion of the process, the sample is again transferred by means of the transfer robot through the vacuum sample-transfer chamber 105 so as to be delivered to another process unit or any of the lock chambers 103 and 104.

The interior of the lock chamber 103 or 104 to which the sample has been delivered is in vacuum condition and after the processed sample has been stored, the gate valve provided for the lock chamber is closed for hermetic sealing and then the interior is pressurized to rise to the atmospheric pressure. After confirmation of the pressure reaching a value equivalent to that in the atmospheric sample-transfer chamber 102, the gate valve on the side of atmospheric sample-transfer chamber 102 is opened and the sample is returned to the original position on the original cassette by means of the transfer robot.

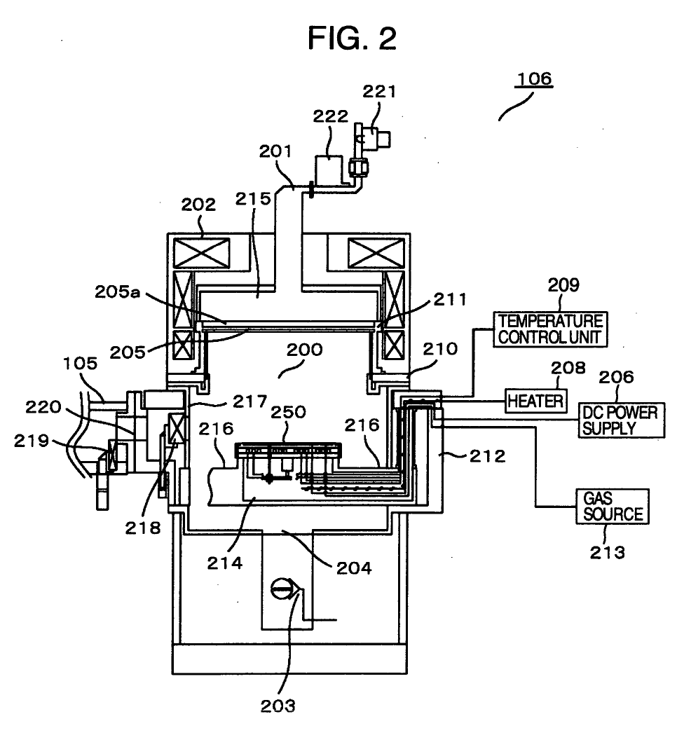

Next, the construction of the vacuum process unit will be described with reference to FIG. 2. The construction of the vacuum process unit of the embodiment shown in the FIG. 1 is schematically illustrated in longitudinal section in FIG. 2.

Especially, illustrated in the figure is the construction of an etching process unit representing one of the vacuum process units 106. In the present embodiment, as shown in FIG. 1, three process units 106 and one process unit 107 are provided as the units for processing the sample. The vacuum process units 106 are connected to three adjacent rear and right sidewall surfaces of the vacuum sample-transfer chamber 105, respectively, and they are used for etching process. On the other hand, the vacuum process unit 107 is connected to the sidewall surface on the left sides, respectively, as viewed from the front of the vacuum sample-transfer chamber 105, and they are used for ashing process.

The vacuum process unit 106 is principally divided into upper and lower components, including an upper processing chamber having a vacuum vessel, a generator of electric field or magnetic field and an evacuator and a lower cuboid-shaped bed housing a controller for adjusting the supply of power and a fluid such as gas and refrigerant to the processing chamber.

The processing chamber of the vacuum process unit 106 in the embodiment of FIG. 1 is schematically illustrated in an enlarged manner in FIG. 2 to schematically show the construction of its principal part. In the figure, a processing chamber 200 is formed in the interior of a vacuum vessel 210 constituting the vessel, and above the processing chamber 200, a waveguide pipe 201 is formed constituting a piping conduit through which an electric wave is fed to supply an electric field to the interior of the processing chamber 200, and at a lower part, a sample stage 250 is provided having its top surface on which an objective to be processed in the form of a substrate-like sample such as a wafer is carried.

The vacuum vessel 210 has its upper sidewall 211 of substantially cylindrical shape which surrounds the outer periphery of a discharge chamber corresponding to the upper part of processing chamber 200 where plasma is formed by the fed electric wave and its lower vessel 212 located below the sidewall 211. The sidewall 211 and the lower vessel 212 are arranged to surround the outer periphery of the sample stage 250 with intervention of a space. In the intervening space, gas, plasma and substances formed by reaction inside the processing chamber 200 are transferred downwards by means of an exhaust unit 203 inclusive of an evacuation pump connected to the bottom of the lower vessel so as to be exhausted through an opening 204 formed in the bottom of the lower vessel 212.

In the processing chamber 200, a shower plate 205 in the form of a circular disc shape constituting the ceiling surface of processing chamber 200 is arranged above the sample stage 250 to oppose the top surface of the sample stage 250. Above the shower plate 205, a window member 205a of circular disc shape made of a dielectric material such as quartz intervenes between the shower plate and a resonance chamber 215 while connecting to the upper end of the sidewall 211 so as to be attached thereto through hermetic seal applied between the interior of the processing chamber 200 and its exterior.

The resonance chamber 215 above the processing chamber 200 surrounded by the sidewall 211 is a cylindrical chamber into which the electric wave is supplied and resonated to take a specified mode, and the waveguide 201 of rectangular or (elliptical) circular sectional form through which the electric wave propagates is disposed being connected to the top of the resonance chamber, having its upper end attached with an electric wave forming means such as a magnetron 221 for generating and transmitting a high-frequency wave such as a microwave. Located at the bottom of the resonance chamber 215 is the window member 205a of circular disc shape made of a dielectric material such as quartz connecting to the upper end of the sidewall 211, thus establishing hermetic seal between the interior of the processing chamber 200 and its exterior. The electric wave resonated in the resonance chamber 215 is admitted to the processing chamber 200 through the window member 205a.

A magnetic field forming unit 202 comprised of, for example, an electromagnetic coils and yokes is arranged above the resonance chamber 215 and externally of the sidewall 211 surrounding the outer periphery of the processing chamber 200, encircling the resonance chamber and the sidewall. In the processing chamber 200, a plasma is generated by the magnetic field supplied from the magnetic field forming unit 202 to the interior of processing chamber 200 and the electric field supplied from the waveguide 201 via the resonance chamber 215 and window member 205a.

A gap is formed between the shower plate 205 and the window member 205a to define a space which is filled up with a processing gas of a mixture of a plurality of kinds of substances supplied from gas feed means not shown, at a given flow rate and mixing ratio. In a portion of shower plate 205 above the top surface of sample stage 250 on which the sample is carried and in parallel with the top surface, a plurality of minute-diameter perforations are formed in communication with the above defined space, so that during the sample processing, the processing gas filling the space migrates into a space above the sample stage 250 inside the processing chamber 200 through the perforations so as to be fed to the space. On the other hand, below the opening 204 formed in the bottom of vacuum vessel 210 and between the opening 204 and the entrance of the evacuation pump of exhaust unit 203, a plurality of vacuum evacuation valves having rotatable flaps capable of rotating for open/close communication are arranged, and in the situation that the interior is not opened to the atmosphere but is maintained at vacuum pressure during the processing or transfer of the sample, the pressure in the processing chamber 200 is controlled by cooperative operation of the vacuum evacuation valves and the evacuation pump.

In processing a sample, the high-frequency wave generated by the magnetron 221 is supplied via a matching box 222 and the waveguide 201 connected thereto and a high-frequency electric field propagating through the waveguide 201 is introduced into the processing chamber 200. Concurrently therewith, the magnetic field generated by the magnetic-field forming unit 202 is fed to the interior of processing chamber 200 and the high-frequency electric field interacts with the magnetic field to excite atoms and molecules of the substances of the processing gas, thus forming the plasma. A wafer representing a to-be-processed substrate-like sample transferred and carried on the top surface of sample stage 250 is applied to an etching process by using the plasma formed above the sample stage 250 in the processing chamber 200, while feeding high-frequency power to the sample stage 250 from an RF bias power source 207.

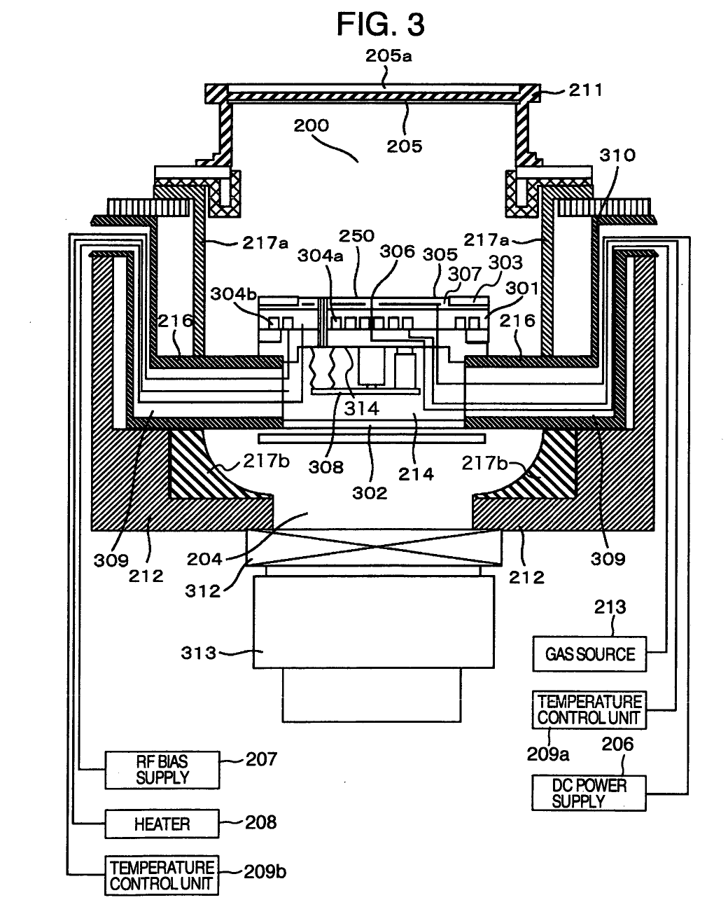

Details of the sample stage 250 and its interior and the flow of wafer processing will be described by also making reference to FIG. 3. The construction of the sample stage 250 in the example of FIG. 2 and the peripheral structure are illustrated in FIG. 3 in an enlarged longitudinal section. In the figure, the peripheral structure including the waveguide 201, resonance chamber 215 magnetic field forming unit 202 and side wall 211 is not illustrated and the path for a heat exchange medium supplied to the sample stage 250 and the like are schematically illustrated.

The sample stage 250 is shaped substantially cylindrical and its center axis is made coaxial with center axes of upper and lower portions of the processing chamber 200 shaped similarly cylindrical, that is, the sample stage is arranged so-to-speak in concentric with the processing chamber. Under the cylindrical sample stage 250, the circular opening 204 is disposed, and the opening 204, the sample stage 250 and the processing chamber 200 are arranged coaxially with one another. The space is formed between the sample stage 250 and the inner wall surface of processing chamber 200 and, the gas for processing introduced from the shower plate 205 to the processing chamber 200, particles in the plasma and substances formed during the wafer processing migrate through the space and exhausted to the outside of the processing chamber 200 through the opening 204 formed below the sample stage 250.

In the space, a plurality of (four in this example) of support beams 216 extending horizontally between the outer sidewall of sample stage 250 and the inner sidewall of processing chamber 200 are arranged. In the present embodiment, the plurality of support beams are located symmetrically with respect to the vertical axis passing through the center of sample stage 250, that is, the center axis of processing chamber 200. Then, arranged in association with the processing chamber of the vacuum process unit 106 in the present embodiment are the sidewall 211 constituting the outer wall of the vacuum vessel 210 and an inner vessel 217 of cylindrical shape located inside the lower vessel 212 to surround the outer periphery of the sample stage 250. The inner vessel 217 includes two members of upper member 217a and lower member 217b arranged above and below the support beam 216, respectively, and the upper member 217a confronts the plasma and the lower member 217b is formed at the bottom center with a circular opening communicating with the opening 204.

The inner wall surface of the inner vessel 217 (217a and 217b), together with the cylindrical inner wall surface of a ring-shaped member for interconnecting the support beams 216 horizontally, is arranged concentrically with the centers of the sample stage 250 and the opening 204, thus, along with the wall surface of upward sidewall 211 confronting the internal processing chamber 200, forming the inner wall surface of the processing chamber 200. With this construction, streams of gas and plasma flowing from the space inside the processing chamber 200 above the sample stage 250 along the periphery of the sample stage 250 can be axially symmetrical and the wafer can be processed uniformly in its peripheral direction.

As described above, in the present embodiment, the inner vessel 217 constituting the inner wall surface and the vacuum vessel 210 arranged exteriorly of the inner vessel are provided to surround the processing chamber 200, and the wafer transferred in the vacuum sample-transfer chamber 105 is then transferred through the interior of each gate so arranged as to pass through each of the inner and outer vessel s. Each gate is opened/closed by means of a gate valve 218 arranged between the inner vessel 217 and vacuum vessel 210 (lower vessel 212) and by means of a gate valve 219 arranged interiorly of a gate 220 formed in the sidewall of vacuum sample-transfer chamber 105 and when these gate valves are closed, the gates are sealed hermetically.

The sample stage 250 includes an inner base 301 in the form of a circular disc made of metal and having high heat transferability, a dielectric film 305 arranged above the top surface of the circular disc to cover it and made of a dielectric material of a mixture containing alumina and yttrium as principal elements, and an electrode 307 in the form of a film arranged inside the dielectric film 305 and connected electrically to a DC power supply 206 through a filter circuit not shown. In order to electrically insulate from the plasma the outer periphery of a circular mount surface on which a wafer is mounted, being covered with the dielectric film 305, and the sidewall of base 301 as well, and also with the aim of protecting them from being sputtered and etched by the plasma, a ceramic cover 303 is laid on the outer peripheral surface of the mount surface and the outer periphery of the sidewall of base 301, covering them.

In the base 301 constituting the sample stage 250, flow channels 304a and 304b are formed concentrically or spirally, and heat exchange media adjusted in temperature or flow rate (speed) by means of temperature regulator units 209a and 209b located externally of the vacuum vessel 210, respectively, are introduced to the respective flow channels so as to adjust the temperature of the base 301 and the sample stage 250 by extension to a desired value. The wafer on the base 301 receives heat from the plasma during being mounted on the sample stage 250 and processed, but by regulating the temperature of the sample stage 250, the temperature of the wafer carried thereon can be adjusted.

In order to improve the heat conduction between the wafer and the sample stage 250 or base 301, a plurality of openings 306 are formed in the top surface of the dielectric film 305, the openings being in communication with a gas source 213 of a gas having heat conductivity, for example, He gas through a gas introduction adjuster, and the He gas is supplied from the openings to a space between the back of the wafer carried on the mount surface and the dielectric film 305. The He gas transfers the heat supplied to the wafer through the dielectric film 305 and base 301, thereby cooling the wafer.

A metal plate 314 is arranged below the base 301 through the insulation member so that the interior and exterior of the processing chamber 200 are sectioned in a hermetically sealed fashion. Especially, in the present embodiment, the sample stage 250 is supported at a medium height in the space inside the processing chamber 200 by means of the support beams 216, so-to-speak, suspended. On the other hand, inside the sample stage 250, an accommodation space 214 is formed in which drive means for pins used for reception/delivery of a wafer and junctions between the sample stage 250 and admission conduits of the heat exchange medium and He gas supplied from the exterior of vacuum vessel 210 are arranged.

The accommodation space 214 includes at least one cylindrical space located below the base 301 of sample stage 250 in the present embodiment and has its center axis concentric with the center axis of the sample stage 250. Further, the accommodation space 214 is arranged in the support beams 216 and in communication with the exterior of the vacuum vessel 210 via through-ducts 309, and the pressure in its interior is equal to or slightly higher than the atmospheric pressure. Since the accommodation space 214 needs to be hermetically sectioned from the space surrounding the sample stage 250 in the processing chamber 200, the space 214 has its interior hermetically sealed from its exterior by means of seal means such as a bellows or an O-ring as will be described later.

Each support beam 216 has each inner duct 309 and one end of the duct 309 communicates with the opening formed in the cylindrical sidewall of the accommodation space 214, and the piping conduits for heat exchange medium and He gas and wiring for feeding high-frequency power from the RF bias power supply 207 are connected to the flow channels 304a and 304b and to the electrode 307 inside the dielectric film 305, through the metal plate 314 constituting the ceiling surface of the accommodation space 214. The other end of the duct 309 is connected to the outer peripheral end of each support beam 216 and communicates with an internal space of a pillar 310 extending vertically to suspend and support the support beam. The heat exchange medium pipe conduit or the He gas pipe conduit inside the duct 309 pass through the space inside the pillar 310 and extend from the upper end thereof to the exterior of the vacuum vessel 210.

A drive mechanism 308 for driving a plurality of (three in the present embodiment) vertically extending rod-like pusher pins 311 including an actuator and arms to which the pins couple at their ends, is arranged below the metal plate 314 in the center of the accommodation space as will be described later. The pusher pin 311 is arranged in a through-channel which passes through the base 301 and dielectric film 305 constituting the sample stage 250 and the insulation member and plate member, having its axis parallel to the axis of the through-channel. In addition, for the sake of preventing the wafer from being applied with non-uniform external force and damaged thereby, each of the pusher pins 311 is arranged axially symmetrically with the center axis of the sample stage 250 located so as to be concentric with the center of the wafer and as to be positioned at a site 60% or 80% of the radius of the wafer.

The vertical or up/down direction in which the drive mechanism 308 inclusive of the actuator drives is set in parallel or in a direction seemed to be substantially parallel with the axis of the pusher pin, and the pusher pins 311 connected to the arms are moved vertically by being interlocked with the operation of actuator. This operation is practiced when unprocessed and processed wafers are received/delivered or interchanged in the processing chamber 200 as will be described later.

In the sample stage 250 of the present embodiment, hermetic seal is applied at the outer periphery of a circular bottom plate 302 between the bottom of accommodation space 214 and the processing chamber 200, especially, the space below the sample stage 250 and above the opening 204 by means of sealing means such as an O-ring. The bottom plate 302 can be detached by a worker when the interior of the apparatus is opened to the atmosphere during maintenance, for instance, enabling the worker to handle members and structures inside the accommodation space 214.

In connection with the vacuum process unit 106, an objective wafer to be applied with a predetermined process is taken out of the lock chamber 103 or 104 by means of the transfer robot while being carried thereon and transferred to the interior of processing chamber 200 inside the vacuum process unit (for example, 106) for practicing the process to be applied. Subsequently, when the wafer carried on the robot reaches a position above the mount surface of the sample stage 250, the operation of the robot is stopped and the wafer is held above the mount surface.

Then, the drive mechanism 308 is driven and the pusher pins 311 are moved upwards and their upper ends are raised to above the dielectric film 305 through its openings. Further, the upper portions of pusher pins 311 are raised to above the robot while the wafer being carried on the upper ends of pusher pins 311 in engagement with the upper ends and the pusher pins hold the wafer at a predetermined position of the upper end. This condition is maintained and after the robot has retracted to the exterior of processing chamber 200, the pusher pins 311 are moved downwards through operation by the actuator until the wafer back surface first contacts the mount surface and are further moved downwards until they reach their lower end positions through the passages.

Next, a DC voltage is applied to the electrode 307 through the DC power supply 206 and the filter circuit which are installed externally of the processing chamber 200 to adsorb and hold the wafer carried on the mount surface by static electricity through the medium of the dielectric film 305. In the present embodiment, the electrode 307 is comprised of a plurality of films which are made to have different polarities, respectively, having a so-called bipolar electrode structure. After completion of movement of the robot to the exterior of the vacuum process unit 106 has been confirmed, the gate valve 218 between the processing chamber 200 and the vacuum sample-transfer chamber 105 is closed to set up hermetic seal between the interior and the exterior.

Under this condition, He gas is supplied from the gas source 213 located exteriorly of the processing chamber 200 to the space formed between the back of the wafer and the top surface of dielectric film 305 through the medium of a gas introduction regulation valve (not shown) for adjusting the gas feed amount and the openings 306 formed in the top surface of dielectric film 305, ensuring that the wafer can be cooled by transferring heat in the wafer to the dielectric film 305 and the base 301. In the base 301, the heat exchange media adjusted to predetermined temperatures by means of the temperature regulator units 209a and 209b is circulated through the channel 304a located on the center side of the sample stage 250 and the channel 304b located on the outer peripheral side of the sample stage. Especially, in the present embodiment, the wafer and the sample stage 250 can be cooled pursuant to intended temperature distributions (temperature profiles) by feeding refrigerants adjusted to different temperatures by means of the temperature regulator units 209a and 209b to the independent channels 304a and 304b, respectively, and circulating them therethrough.

The processing gas is supplied to the interior of processing chamber 200 through perforations formed in the shower plate 205, and simultaneously, the interior of processing chamber 203 is evacuated by operating the vacuum evacuation valve 312 of exhaust unit 203 and the vacuum pump 313 representing the evacuation pump so that the pressure may be adjusted to a given value. Further, the processing gas undergoes plasma formation by electric field supplied from the waveguide 201 via the resonance chamber 215 and window member 205a and by the magnetic field supplied from the magnetic field forming unit 202, and the plasma is formed above the wafer in the processing chamber 200. Further, the high-frequency power from the RF bias power supply 207 installed in the exterior of the processing chamber 200 is applied to the base 301 constituting the sample stage 250 via a matching box (not shown), and then processing is started while assisting an etching reaction by leading ions contained in the plasma onto the wafer in accordance with the potential difference between bias potential due to an RF bias formed above the top surface of wafer and plasma potential.

At the termination of the processing, the plasma and RF bias is stopped and supply of the DC voltage to the electrode 307 is stopped to reduce and remove the force of static electricity. Under this condition, the actuator is again driven and the pusher pins 311 are raised through the individual passages to bring their upper ends in contact with the back surface of the wafer and further moved to above the dielectric film 305 so as to raise the wafer to above the sample stage 250, thus causing the wafer to move to the upper end position of the pusher pins 311.

Thereafter, the gate valve 218 between the processing chamber 200 and the vacuum sample-transfer chamber 105 is opened and the robot moves to below the wafer in the processing chamber 200 and stops there, and the pusher pins 311 move to below the robot by operating the actuator, thus delivering the wafer to the robot. As the robot retracts to the exterior of the processing chamber 200, the wafer is taken out of the processing chamber 200. Thereafter, the wafer is transferred to a different vacuum process unit or to any of the lock chamber 103 or 104 by means of the robot and a different unprocessed wafer is delivered by means of the robot to the processing chamber 200 from which the processed wafer has been taken out.

Since in the present embodiment the heat exchange medium is supplied at a regulated temperature lower than the temperature, there is a possibility that the piping conduit for the heat exchange medium extending through the interior of duct 309 and connecting to the sample stage 250 inside the accommodation space 214, especially, its junction will dew-condensed to raise a problem of leak or corrosion. Accordingly, in the plasma processing apparatus of the present embodiment, gas (ambient gas) heated by a heater 208 located externally of the vacuum vessel 210 is fed to the interior of accommodation space 214 through the duct 309, and simultaneously, gas in the accommodation space 214 is exhausted to the exterior of the vacuum vessel 210.

The heater is a unit for heating the gas to a temperature higher than that of the and blowing it out. The gas at the high temperature is blown out to the interior of the accommodation space 214 via a tube 414 of small diameter inserted and arranged inside the duct 309 so that the gas in the accommodation space 214 is blown out by the gas at high temperature so as to be exhausted to the exterior of the vacuum vessel 210 via the duct 309. In this manner, the dew-condensation inside the accommodation space 214 and the adverse influence caused thereby can be reduced.

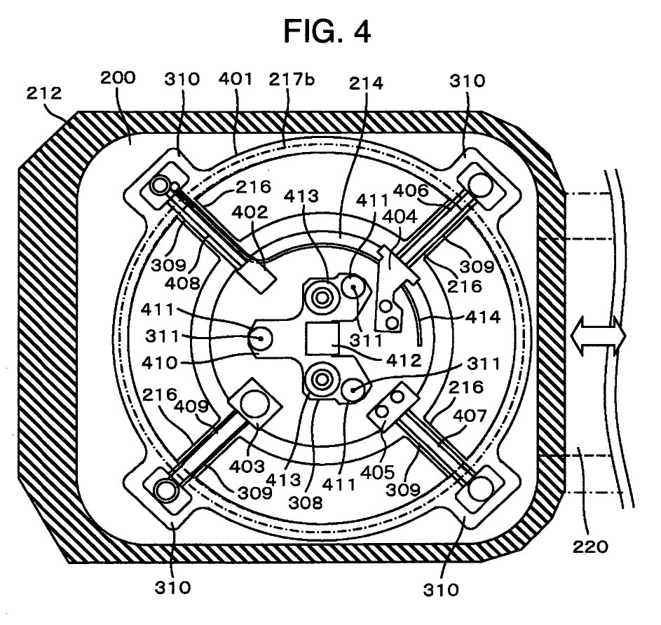

Referring now to FIG. 4, the construction of vacuum vessel 210 and sample stage 250 in the example of FIG. 3 is schematically illustrated in cross-sectional view form. Illustrated in FIG. 4 is a cross-section taken at a vertically intermediate height position of the support beam 216 in FIG. 3.

As shown in the figure, in the substantially rectangular space inside the lower vessel 212 of vacuum vessel 210 of the present embodiment, the inner vessel 217 having the cylindrical inner wall surface and the ring-shaped member 401 for mutually coupling the support beams 216 are arranged and they constitute the processing chamber 200 and its inner wall. Inside the ring-shaped member 401, the sample stage 250 connected to the four support beams 216, disposed axially symmetrical, is arranged concentrically with the vacuum vessel 250.

Inside the sample stage 250, the cylindrical accommodation space 214 is arranged below the metal plate 314 under the base 301 and the drive mechanism 308 for pusher pins 311 is located in the center of the accommodation space. On the other hand, on the outer peripheral side of the accommodation space, there are provided a joint 402 of a piping conduit for the He gas flowing from the gas source 213 to the sample stage 250 through the interior of the support beam 216, a joint 403 of a piping conduit for the high-frequency power from the RF bias power supply 207, and joints 404 and 405 of piping conduits for the refrigerants from the temperature regulator units 209a and 209b.

The substantially rectangular space inside the lower vessel 212 of vacuum process unit 106 according to the present embodiment has the pillars 310 located at each corner, to make the outer diameter of the vacuum vessel 210 as small as possible to advantage. The two support beams 216 arranged on the right side (on the side of vacuum sample-transfer chamber 105) of the sample stage 250 on the drawing are respectively connected to the pillars 310, and refrigerant piping conduits 406 and 407 arranged in the ducts 309 are connected, at two corners of the vacuum sample-transfer chamber 105 of vacuum vessel 210, to external refrigerant pipes through the ducts inside the respective pillars 310. In the figure, each of the refrigerant piping conduits 406 and 407 is illustrated as being a single pipe but, since the refrigerant flowing through each pipe is circulated by way of the respective temperature regulator units 209a/209b and channels 304a/304b, each piping conduit is provided with at least two channels for feeding the refrigerant to the channels 304a and 304b and for exhausting the refrigerant from these channels.

On the left side on the drawing, inside the ducts 309 internal of the two support beams 216, a He piping conduit 408 for circulation of the He gas and a cable 409 for supply of the high-frequency power are arranged, respectively. The refrigerant piping conduits 406 and 407, He piping conduit 408 and cable 409 lead to openings of the respective ducts 309 at the cylindrical inner wall of the accommodation space 214, and there, they are bent upwards by means of the joints 402, 403, 404 and 405, respectively, so as to be connected to the bottom of the metal plate member 314 constituting the ceiling surface of the accommodation space 214. The respective joints 402, 403, 404 and 405 are fixedly clamped to the inner wall of the accommodation space 214 by means of bolts, for instance.

Especially, the joints 404 and 405 for the refrigerant piping conduits 406 and 407, respectively, are metal blocks having a flat outer wall and each is arranged so as to jut out of the inner wall surface to the center of the accommodation space 214, being connected at their upper surfaces to pipes coupled to the central channel 304a and the outer peripheral channel 304b. Structurally, each of the two blocks representing the joints 404 and 405 has its bottom of a flat surface parallel to the bottom of accommodation space 214 with intervention of a proper gap, its side which is a surface vertical to the bottom surface, and its top which is a flat surface parallel to the ceiling surface of the accommodation space 214 with intervention of a proper gap, thus forming a block being rectangular in section. The height of the block is determined in such a manner that the block is at the level nearly equal to or slightly lower than the outer periphery of the accommodation space 214 in which the block is located and the block substantially occupies the accommodation space 214 in the height direction.

As described previously, the drive mechanism 308 for pusher pins 311 is located in the center of the accommodation space 214. The three pusher pins 311 are arranged symmetrically to the center axis of the accommodation space 214 (sample stage 250) and they connect at their lower ends to upper ends of a Y-shaped plate member constituting arms 410. Provided for each pusher pin 311 is a metal bellows 411 which circularly encircles the periphery of the pusher pin to set up hermetic seal between the interior and exterior of the bellows.

The bellows hermetically is connected at its upper end to the metal plate 314 constituting the ceiling surface of the accommodation space 214 and at its lower end to the upper surface of the arm 410. By sealing the individual portions, the interior of each bellows that communicates with the interior of the processing chamber 200 via the through-hole or passage through which the pusher pin moves up and down and that is decompressed can be sectioned hermetically from the exterior of each bellows that communicates with the exterior of the vacuum chamber 210 through the duct 309 and that is at the ambient pressure (or slightly higher pressure). The bellows 411 has a cornice structure so that it may telescopically move by operating the actuator 412 as the pusher pin 311 and arm 410 move up and down.

Arranged in the center of the accommodation space 214 is the actuator 412 which is connected to the arm 410 and is telescopic vertically to move the arm 410 up and down. The actuator 412 has a square-pole shape and is connected to at its lower end to the top surface of arms 410 and at its upper end to the ceiling surface of accommodation space 214 so as to move the arms 410 and pusher pins 311 up and down in relation to the ceiling surface or by extension to the base 301 and dielectric film 305. Further, in the vertical direction on the drawing, cylindrical linear guides 413 are arranged adjacently to the actuator 412. The linear guide includes cylindrical columns of different diameters forming a cylinder and a piston which are coaxial and concentric with each other, having one end connected to the arm 410 and the other end connected to the ceiling surface of the accommodation space 214. As the actuator 412 operates, the linear guide moves telescopically along its axis to thereby reduce deviation of the up/down movement of the pusher pin 311, thus suppressing the tendency of the pusher pin toward contacting or scratching the wall surface of the through-hole.

The drive mechanism 308 constructed as above is coupled to the bottom of the metal plate 314 constituting the ceiling surface of accommodation space 214 and moves telescopically up and down. In the maximally stretched condition (at the lower end where the pusher pin 311 is completely housed in the through-hole), it approaches the bottom of the accommodation space 214. Further, in the present embodiment, these pusher pins 311 are arranged vertically symmetrically with respect to a dotted and dashed line in the drawing extending in the right and left direction through the center of the sample stage 250. The right and left directional dotted and dashed line is parallel to the transfer direction of the wafer shown by an arrow in the drawing and the pusher pins 311 are arranged symmetrically to the transfer direction of the wafer. The pusher pins 311 and bellows 411 arranged on the side of the vacuum transfer chamber 105 (on the axis of gate 220) are located symmetrically to the side of gate 220 and the support beams 216 arranged in an axially symmetric fashion are also located symmetrically to the axis of gate 220.

With this arrangement, the direction in which the individual ducts 309 and the internal refrigerant piping conduits 406 and 407 are arranged is directed, at the central portion of the processing chamber 200, to in between the pusher pins 311 on the side of vacuum transfer chamber 105 (on the side of gate 220). Also, the block of joint 404 connects the central channel 304a to the refrigerant piping conduits 406 and is located so as to project to between the pusher pins 311. Accordingly, between the joints 404 and 405, a prescribed space is defined which is surrounded by the cylindrical inner wall of the accommodation space 214 and by the vertically extending plane of the joints 404 and 405.

In the present embodiment, a tube 414 is provided which extends from the interior of the duct 309, on the upper left side in the drawing, in which the He piping conduit 408 is located, by way of the outer periphery of the accommodation space 214, to the space between the joints 404 and 405 and opens there. The other end of the tube 414 on the side of duct 309 passes through the interior of pillar 310 to be connected to the heater 208 arranged exteriorly of the vacuum vessel 210. As described previously, the ambient gas heated by the heater 208 and fed at a given flow rate flows inside the tube 414 via the duct 309 to the opening of tube 414 suspending in the space between the blocks of refrigerant joints 404 and 405 inside the accommodation space 214, being eventually supplied to the interior of accommodation space 214 from the opening.

The blown out ambient gas higher in temperature than the refrigerant or the surface temperature of the joints 404 and 405 impinges on the sidewall of the block of joint 405 and is reflected thereby to impinge on the sidewall of the other joint 404. The gas flow as above can be achieved efficiently by the aforementioned arrangement and shape of the blocks of joints 404 and 405, and in addition, the joints 404 and 405 thus heated suppress the dew condensation. The block of joint 404 is recessed in the surface of the sidewall confronting the joint 405, especially, in the neighborhood of the sidewall of accommodation space 214 or the end of the refrigerant piping conduit 406 at the opening of duct 309, thereby ensuring that the flow-in ambient gas can be guided by the reflection at the recess and heat transfer is carried out by causing the high-temperature gas to efficiently contact the surface of the site more liable to undergo dew condensation.

Further, the space between the joints 404 and 405 is distant from the center of the sample stage 250 (accommodation space 214) but in this space, the drive mechanism for pusher pins 311 located in the central part of the accommodation space 214 is arranged. In the drive mechanism 308 in the present embodiment, the columnar bellows 411, actuator 412 and linear guides 413 are adjacently arranged between the plate member of arm 410 and the ceiling surface of the accommodation space 214.

Accordingly, the ambient gas introduced to the space between the joints 404 and 405 flows at low conductance on account of many obstacles when directing from the gap of the space to the central side, so that a part of the ambient gas flows through a gap between the sidewall of each of the blocks of joints 404 and 405 and the bellows 411 of drive mechanism 308. In other words, the ambient gas flows on the sidewall surfaces of the block of joints 404 and 405 confronting the bellows 411, and therefore, the joints 404 and 405 can be heated more efficiently. The blocks of joints 404 and 405 are arranged so as to define gaps upwardly and downwardly of them in the vertical direction and the ambient gas supplied to in between defined by the joints also flows into the interior of the accommodation space 214 by way of the gaps, thus heating the blocks.

As described above, the ambient gas flowing to the central part of accommodation space 214 through the gap between the members inside the accommodation space 214 passes from the opening of duct 309 on the left upper side in the drawing and through the interior of duct 309, eventually being exhausted to the exterior of the vacuum vessel 210 by way of the interior of the pillar 310. In this manner, according to the present embodiment, the heated ambient gas is circulated through the space between the joints 404 and 405 and through the duct 309 of support beams 216 opposing these joints by way of the intervening central part to the exterior of the vacuum vessel 210. Because of this flow, the occurrence of the dew-condensation inside the accommodation vessel 214 attributable to the supply of the heat exchange medium of lower temperature than the ambient gas temperature to the sample stage 250 can be suppressed.

As set forth so far, according to the present embodiment, a highly reliable plasma process unit can be provided which can suppress dew-condensation and corrosion even when the heat exchange medium at low temperature is supplied to the sample stage 250, thereby suppressing the adverse influence leading to trouble shooting in operation, maintenance and parts exchange at short intervals of periods.

It should be further understood by those skilled in the art that although the foregoing description has been made on embodiments of the invention, the invention is not limited thereto and various changes and modifications may be made without departing from the spirit of the invention and the scope of the appended claims.

1. A plasma processing apparatus comprising:
a substantially cylindrical-shaped processing chamber arranged in a vacuum vessel and having its decompressed interior to which a gas for processing is fed and in which a plasma is formed;
a substantially cylindrical-shaped sample stage which is arranged inside said processing chamber with a space between said sample stage and the inner sidewall surface of said processing chamber surrounding said sample stage and is adapted to carry a sample such as a wafer to be processed on its top surface;
an opening formed in the bottom of said processing chamber below said sample stage for exhausting the processing gas;
a channel for medium which is formed helically or concentrically in said sample stage and through which a heat exchange medium for adjusting temperature of said sample stage flows;
beams arranged horizontally between said sample stage and an inner sidewall of said processing chamber to support said sample stage in said processing chamber;
a cylindrical space defined in an interior of said sample stage below said channel and having its interior in communication with the atmospheric pressure;
a coupling path formed inside each of said beams to communicate the inner wall of said cylindrical space with the atmospheric-pressure space external of said vacuum vessel;
a plurality of piping conduits for medium which are so formed in said coupling paths as to connect to said channel and through which said heat exchange medium flows;
a drive mechanism arranged in the center of the interior of said cylindrical space to drive a plurality of pins for up/down movement of a wafer above top surface of said sample stage;
a plurality of metal blocks arranged around an outer periphery of said drive mechanism to cover a plurality of junctions of said plurality of piping conduits for medium connected to said sample stage; and
a gas supply path which passes through the interior of said coupling path and has an opening between said plurality of blocks inside said cylindrical space and said drive mechanism, and through which a gas heated to a given temperature is circulated, wherein the gas in said cylindrical space is exhausted to the exterior of said vacuum vessel by way of said coupling path.

2. A plasma processing apparatus according to claim 1, wherein said refrigerant piping conduit has its junction connected to a ceiling surface of said cylindrical space through an opening formed in the inner sidewall of said cylindrical space, and said metal block has a flat surface parallel to the ceiling surface or a bottom surface of said cylindrical space and a side surface set up at right angles to the flat surface.

3. A plasma processing apparatus according to claim 1, wherein said sample stage is arranged concentrically with respect to said processing chamber and supported by a plurality of said beams, and at least one of said plurality of piping conduits for medium and said each gas supply path are arranged in said coupling path formed in each of said plural beams.

4. A plasma processing apparatus according to claim 2, wherein said sample stage is arranged concentrically with respect to said processing chamber and supported by a plurality of said beams, and at least one of said plurality of piping conduits for medium and said each gas supply path are arranged in said coupling path formed in each of said plural beams.

5. A plasma processing apparatus according to claim 1, wherein said sample stage is arranged concentrically with respect to said processing chamber and supported by three or more of said beams, and each of said plurality of piping conduits for medium and said gas supply path are arranged in said coupling paths formed in each of said plurality of beams.

6. A plasma processing apparatus according to claim 2, wherein said sample stage is arranged concentrically with respect to said processing chamber and supported by three or more of said beams, and each of said plurality of piping conduits for medium and said gas supply path are arranged in said coupling paths formed in each of said plurality of beams.

7. A plasma processing apparatus according to claim 3, wherein in the center portion and an outer peripheral side of said sample stage, first and second medium channels are provided through which heat exchange media adjusted to different temperatures are circulated, respectively; first and second medium piping conduits connected to said respective first and second medium channels and arranged in an interior of individual coupling paths in said respective beams are provided; and first and second metal blocks arranged to cover junctions of said first and second medium piping conduits, respectively, are provided, wherein the gas from said gas supply path is supplied to between said first and second metal blocks.

8. A plasma processing apparatus according to claim 4, wherein in the center portion and an outer peripheral side of said sample stage, first and second medium channels are provided through which heat exchange media adjusted to different temperatures are circulated, respectively; first and second medium piping conduits connected to said respective first and second medium channels and arranged in an interior of individual coupling paths in said respective beams are provided; and first and second metal blocks arranged to cover junctions of said first and second medium piping conduits, respectively, are provided, wherein the gas from said gas supply path is supplied to between said first and second metal blocks.

9. A plasma processing apparatus according to claim 3, wherein said plurality of beams are arranged around said sample stage arranged concentrically with respect to said processing chamber so as to be symmetrical to a vertical center axis of said sample stage.

10. A plasma processing apparatus according to claim 4, herein said plurality of beams are arranged around said sample stage arranged concentrically with respect to said processing chamber so as to be symmetrical to a vertical center axis of said sample stage.

11. A plasma processing apparatus according to claim 1, wherein said drive mechanism includes said plural pins arranged around the center of said sample stage in the interior thereof, a plurality of arms each connected to bottom of each of said plurality of pins and extending from the center of said sample stage to the outer periphery thereof, and an actuator connected to said arms and being vertically telescopic between the ceiling surface of said cylindrical space and said arm, and wherein a telescopic bellows is provided, being arranged around each of said plurality of pins and connected to the ceiling surface of said cylindrical space, having its interior hermetically sealed from its exterior.

12. A plasma processing apparatus according to claim 2, wherein said drive mechanism includes said plural pins arranged around the center of said sample stage in the interior thereof, a plurality of arms each connected to bottom of each of said plurality of pins and extending from the center of said sample stage to the outer periphery thereof, and an actuator connected to said arms and being vertically telescopic between the ceiling surface of said cylindrical space and said arm, and wherein a telescopic bellows is provided, being arranged around each of said plurality of pins and connected to the ceiling surface of said cylindrical space, having its interior hermetically sealed from its exterior.

13. A plasma processing apparatus according to claim 3, wherein said drive mechanism includes said plural pins arranged around the center of said sample stage in the interior thereof, a plurality of arms each connected to bottom of each of said plurality of pins and extending from the center of said sample stage to the outer periphery thereof, and an actuator connected to said arms and being vertically telescopic between the ceiling surface of said cylindrical space and said arm, and wherein a telescopic bellows is provided, being arranged around each of said plurality of pins and connected to the ceiling surface of said cylindrical space, having its interior hermetically sealed from its exterior.

14. A plasma processing apparatus according to claim 4, wherein said drive mechanism includes said plural pins arranged around the center of said sample stage in the interior thereof, a plurality of arms each connected to bottom of each of said plurality of pins and extending from the center of said sample stage to the outer periphery thereof, and an actuator connected to said arms and being vertically telescopic between the ceiling surface of said cylindrical space and said arm, and wherein a telescopic bellows is provided, being arranged around each of said plurality of pins and connected to the ceiling surface of said cylindrical space, having its interior hermetically sealed from its exterior.

15. A plasma processing apparatus according to claim 5, wherein said drive mechanism includes said plural pins arranged around the center of said sample stage in the interior thereof, a plurality of arms each connected to bottom of each of said plurality of pins and extending from the center of said sample stage to the outer periphery thereof, and an actuator connected to said arms and being vertically telescopic between the ceiling surface of said cylindrical space and said arm, and wherein a telescopic bellows is provided, being arranged around each of said plurality of pins and connected to the ceiling surface of said cylindrical space, having its interior hermetically sealed from its exterior.

16. A plasma processing apparatus according to claim 6, wherein said drive mechanism includes said plural pins arranged around the center of said sample stage in the interior thereof, a plurality of arms each connected to bottom of each of said plurality of pins and extending from the center of said sample stage to the outer periphery thereof, and an actuator connected to said arms and being vertically telescopic between the ceiling surface of said cylindrical space and said arm, and wherein a telescopic bellows is provided, being arranged around each of said plurality of pins and connected to the ceiling surface of said cylindrical space, having its interior hermetically sealed from its exterior.

17. A plasma processing apparatus according to claim 7, wherein said drive mechanism includes said plural pins arranged around the center of said sample stage in the interior thereof, a plurality of arms each connected to bottom of each of said plurality of pins and extending from the center of said sample stage to the outer periphery thereof, and an actuator connected to said arms and being vertically telescopic between the ceiling surface of said cylindrical space and said arm, and wherein a telescopic bellows is provided, being arranged around each of said plurality of pins and connected to the ceiling surface of said cylindrical space, having its interior hermetically sealed from its exterior.

18. A plasma processing apparatus according to claim 8, wherein said drive mechanism includes said plural pins arranged around the center of said sample stage in the interior thereof, a plurality of arms each connected to bottom of each of said plurality of pins and extending from the center of said sample stage to the outer periphery thereof, and an actuator connected to said arms and being vertically telescopic between the ceiling surface of said cylindrical space and said arm, and wherein a telescopic bellows is provided, being arranged around each of said plurality of pins and connected to the ceiling surface of said cylindrical space, having its interior hermetically sealed from its exterior.

19. A plasma processing apparatus according to claim 9, wherein said drive mechanism includes said plural pins arranged around the center of said sample stage in the interior thereof, a plurality of arms each connected to bottom of each of said plurality of pins and extending from the center of said sample stage to the outer periphery thereof, and an actuator connected to said arms and being vertically telescopic between the ceiling surface of said cylindrical space and said arm, and wherein a telescopic bellows is provided, being arranged around each of said plurality of pins and connected to the ceiling surface of said cylindrical space, having its interior hermetically sealed from its exterior.

20. A plasma processing apparatus according to claim 10, wherein said drive mechanism includes said plural pins arranged around the center of said sample stage in the interior thereof, a plurality of arms each connected to bottom of each of said plurality of pins and extending from the center of said sample stage to the outer periphery thereof, and an actuator connected to said arms and being vertically telescopic between the ceiling surface of said cylindrical space and said arm, and wherein a telescopic bellows is provided, being arranged around each of said plurality of pins and connected to the ceiling surface of said cylindrical space, having its interior hermetically sealed from its exterior.
